(19) United States
(12) Patent Application Publication
(10) Pub. No.: US 2006/0236197 A1
(43) Pub. Date: Oct. 19, 2006

(54) Transmission method combining trellis coded modulation and low-density parity check code and architecture thereof

(76) Inventors: Chien-Ching Lin, Shueishang Township (TW); Hsie-Chia ` Chang, Keelung City (TW); Chen-Yi Lee, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/225,081

(22) Filed: Sep. 14, 2005

(30) Foreign Application Priority Data
Apr. 1, 2005 (TW) 94110448

(51) Int. Cl. H03M 13/00

(52) U.S. Cl. 714/758

(57) ABSTRACT

The present invention discloses a method combining Trellis Coded Modulation (TCM) and Low-Density Parity Check (LDPC) code and the architecture thereof, which incorporates TCM with LDPC code having better error-correction capability to promote transmission quality and to define TCM of different transmission rates. Further, TCM can utilize less number of states to outperform the conventional spreading so that the hardware complexity in high-speed transmission can be reduced.

### BACKGROUND OF THE INVENTION

1. Field of the Invention

The present invention relates to a data transmission technology of communication system, particularly to a transmission method combining Trellis Coded Modulation (TCM) and Low-Density Parity Check (LDPC) code and the architecture thereof.

2. Description of the Related Art

Generally speaking, the operational process of a communication system proceeds from a transmitter through an encoding, modulation, and a transmission medium to a receiver, and those steps will be restored in reverse order at the receiver side. The transmission medium is usually referred to as a channel which can be wired or wireless.

A Forward Error Correction (FEC) technology, which is usually used to protect a data from error induced by noise in data transmission process, is to add a segment of redundancy (check code) to the original data when the transmitter utilizes a channel encoder to undertake encoding. Therefore, an erroneous data induced by noise interference during transmission can be restored into the correct data at the receiver side via a technology of error correction to ensure allowable data loss. The FEC technology usually includes BCH code, Reed-Solomon code, Convolutional code, Turbo code, Low-Density Parity Check (LDPC) code, etc.

In the application of LDPC to a practical communication system, a corresponding LDPC code should be defined according to different coding rate, i.e. additional Read Only Memory (ROM) is needed to store a Generator Matrix G and a Parity Check Matrix H. Moreover, a large number of multiplexers are also necessary for switching datapath in various code definitions. The increased hardware complexity causes difficult circuit implementation and degrades the decoder throughput.

In the other side, the digital modulation technology transforms a digital signal into a sinusoidal signal (called modulated signal); thus, the bandwidth efficiency and frequency spectrum have been determined according to the type of modulator. The related technologies currently adopted by the digital wireless communication system include: BPSK, QPSK, π/4-DQPSK, etc. In 1982, G. Ungerboeck proposed a set-partition-based Trellis Coded Modulation (TCM) to combine channel coding and digital modulation into one, which increases the number of signal states of the signal constellation in channel without lowering data rate or raising bandwidth and increases the redundant information of transmission signal to enlarge the Euclidean distance between signal sequences so that error-resistance capability in signal transmission can be improved and significant coding gain can be obtained. In short, Trellis Coded Modulation (TCM) is a high efficient ECC technology.

The conventional standards, such as DSL, ITU-T J.83, recognize TCM as an independent block, wherein TCM does not closely associate with other error correction codes. In realizing that, the present invention proposes a transmission method combining Trellis Coded Modulation (TCM) that provides channel values and Low-Density Parity Check (LDPC) code and the architecture thereof in order to raise the overall transmission efficacy of communication system and to solve the aforementioned additional hardware complexity.

### SUMMARY OF THE INVENTION

The primary objective of the present invention is to provide a transmission method and architecture thereof, which incorporates TCM with LDPC code having better error-correction capability to promote transmission quality and to define different transmission rates.

Another objective of the present invention is to provide a transmission method combining Trellis Coded Modulation (TCM) and Low-Density Parity Check (LDPC) code and the architecture thereof, which can achieves better transmission performance and can reduce the hardware complexity in high-speed data transmission.

To achieve the aforementioned objectives, the present invention's transmission method and architecture thereof comprises the following steps: firstly, the transmitter utilizes a LDPC encoder to encode a piece of incoming data into LDPC codewords and utilizes a TCM encoder to encode and modulate the LDPC codewords into TCM codewords, which is further transformed by a modem and then sent out via a transmission channel. In a receiver-side, the modem receives and transforms the TCM codewords by using a Viterbi decoder to decode the TCM codewords into LDPC codewords; finally, a LDPC decoder is applied to decode the LDPC codewords into the original data.

To enable the objectives, technical contents, characteristics and accomplishments of the present invention to be more easily understood, the embodiments are to be described below in detail in cooperation with the attached drawings.

### BRIEF DESCRIPTION OF THE DRAWINGS

FIG. 1 is the schematic diagram of the transmission architecture according to one aspect of the present invention.

FIG. 2 is the schematic diagram showing the simulation of the transmission efficacy of the present invention.

### DETAILED DESCRIPTION OF THE INVENTION

In the norms of communication, it is always hard to have a better transmission efficacy, however, still maintaining the same hardware complexity. As exemplified by the ultra-wideband communication system, the Convolutional code with large number of states is defined to improve the transmission efficacy; however, a transmission rate as high as 480 Mb/s brings about an incredible hardware complexity. With respect to the signal attenuation in a communication system, particularly in a high-speed one (such as ultra-wideband system), the present invention proposes a novel method to incorporate TCM with LDPC code having better error-correction capability to promote transmission quality and to define different transmission rates via combining those two encoding methods.

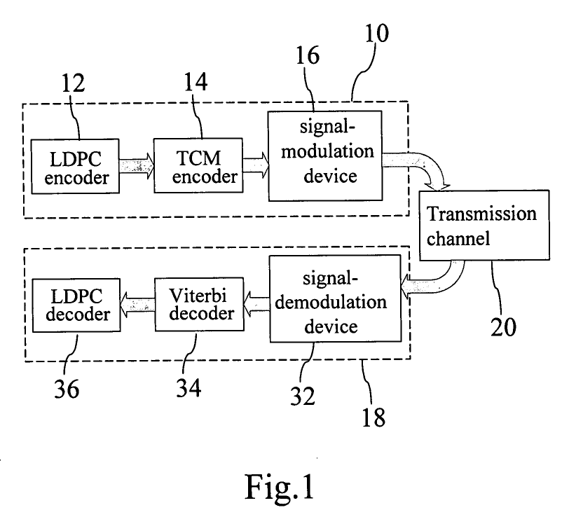

Referring to FIG. 1 the schematic diagram of the transmission architecture according to one aspect of the present invention, a transmission channel 20 exists between a transmitter side 10 and a receiver side 30. The transmitter side 10 comprises a LDPC encoder 12, a TCM encoder 14, and a signal-modulation device 16, and the receiver side 30 comprises a signal-demodulation device 32, a Viterbi decoder 34, and a LDPC decoder 36.

When transmitting a data, the LDPC encoder 12 in the transmitter side 10 receives a piece of incoming data and performs a LDPC encoding to convert the piece of incoming data into LDPC codewords, which is then sent to the TCM encoder 14; the TCM encoder 14 utilizes TCM technology to encode and modulate the LDPC codewords into TCM codewords. As the TCM coding rate is adjustable, the TCM encoder 14 can adopt different TCM to define different coding rate of the LDPC codewords. The signal-modulation device 16 converts the TCM codewords into transmissible signal, which is then sent out via the wired or wireless transmission channel 20.

The signal-demodulation device 32 of the receiver side 30 receives and converts the TCM codewords sent from the transmitter side 10. The Viterbi decoder 34 decodes the received TCM codewords into LDPC codewords, wherein the Viterbi decoder 34 can be a MAP decoder or a SOVA (Soft Output Viterbi Algorithm) decoder, and the LDPC decoder 36 decodes the LDPC codewords into the original data.

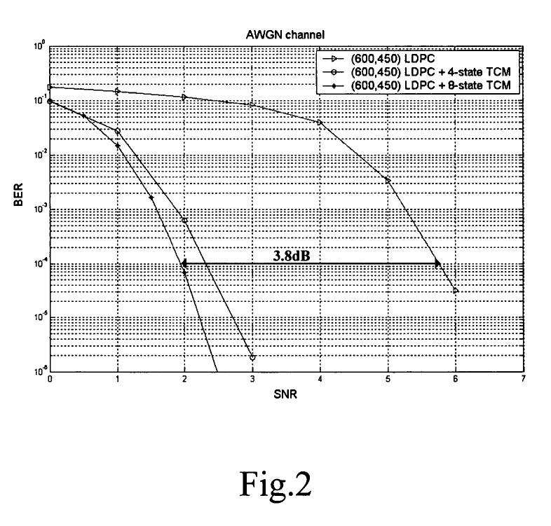

In theory, ½ spreading rate can gain 3 dB of performance in Additive White Gaussian Noise (AWGN) channel; however, in practical circuit, only 2 dB can be achieved. Referring to FIG. 2 the schematic diagram showing the simulation of the performance of the present invention, 8-state TCM can gain about 3.8 dB of performance, and 4-state TCM can still gain 3.5 dB of performance. Furthermore, less number of TCM states and lower hardware complexity not only means better transmission efficiency, but also enables the design of the system's coding rate to be more flexible. The (600,450) LDPC code in FIG. 2 has an efficacy equivalent to that of 64-state Convolutional code defined by ultra-wideband system but has lower hardware complexity in the practical circuit for high-speed data transmission application.

In encoding and decoding of LDPC code, different coding rates need corresponding ROM tables; however, combining LDPC code with TCM can solve the additional hardware complexity, and combining TCM with LDPC code can also increase the performance of high-speed transmission for TCM.

In summary, the transmission method and architecture proposed by the present invention is to incorporate TCM with LDPC code having better error-correction capability to promote transmission quality and define different transmission rates so as to obtain better transmission efficacy and reduce the hardware complexity in high-speed data transmission; thereby, both better transmission efficacy and lower hardware complexity can be simultaneously achieved. Thus, the present invention can be applied to various wireless communication systems, such as Digital Video Broadcasting-Terrestrial (DVB-T), Wireless Local Area Network (WLAN), Wideband, Ultra-Wideband (UWB), etc.

Those embodiments described above are only to clarify the technical contents and characteristics of the present invention so that the persons skilled in the art can understand, make, and use the present invention but not intended to limit the scope of the present invention. Any equivalent modification and variation according to the spirit of the present invention is to be included within the scope of the present invention.

What is claimed is:

1. A transmission method combining Trellis Coded Modulation (TCM) and Low-Density Parity Check (LDPC) code, comprising the following steps:
performing a LDPC encoding to convert a piece of incoming data into LDPC codewords;
performing a TCM encoding and modulation to convert said LDPC codewords into TCM codewords;
transforming said TCM codewords into transformed TCM codewords and sending said transformed TCM codewords out via a transmission channel;
receiving said transformed TCM codewords and utilizing a Viterbi decoding technology to decode said transformed TCM codewords into said LDPC codewords; and
performing a LDPC decoding to reduce said LDPC codewords into the original data.

2. The transmission method combining Trellis Coded Modulation (TCM) and Low-Density Parity Check (LDPC) code according to claim 1, wherein in said TCM encoding, different TCM can be adopted to define different coding rates of said LDPC codewords to enable said coding rates of said LDPC codewords to be adjustable.

3. The transmission method combining Trellis Coded Modulation (TCM) and Low-Density Parity Check (LDPC) code according to claim 1, wherein said transforming said TCM codewords is utilizing a modem to perform signals transformation.

4. The transmission method combining Trellis Coded Modulation (TCM) and Low-Density Parity Check (LDPC) code according to claim 1, wherein said Viterbi decoding technology is to perform decoding with a MAP decoder or a Soft Output Viterbi Algorithm (SOVA) decoder.

5. The transmission method combining Trellis Coded Modulation (TCM) and Low-Density Parity Check (LDPC) code according to claim 1, wherein said transmission channel can be a wired one or a wireless one.

6. A transmission architecture combining Trellis Coded Modulation (TCM) and Low-Density Parity Check (LDPC) code, comprising:
a transmitter side, receiving a piece of data, further comprising: a LDPC encoder, a TCM encoder, and a signal-modulation device, wherein said LDPC decoder performs a LDPC encoding to convert said piece of data into LDPC codewords; said TCM encoder performs a TCM encoding and modulation to convert said LDPC codewords into TCM codewords; and said signal-modulation device transforms said TCM codewords into transformed TCM codewords, which is then sent out;
a transmission channel, utilized to transmit said transformed TCM codewords; and
a receiver side, comprising: a signal-demodulation device, a Viterbi decoder, and a LDPC decoder, wherein said signal-demodulation device receives and transforms said transformed TCM codewords coming from said transmitter side; said Viterbi decoder decodes TCM codewords into said LDPC codewords; and said LDPC decoder reduces said LDPC codewords into the original data.

7. The transmission architecture combining Trellis Coded Modulation (TCM) and Low-Density Parity Check (LDPC) code according to claim 6, wherein said TCM encoder adopts different TCM to define different coding rates of said LDPC codewords to enable said coding rates of said LDPC codewords to be adjustable.

8. The transmission architecture combining Trellis Coded Modulation (TCM) and Low-Density Parity Check (LDPC) code according to claim 6, wherein said Viterbi decoder can be a MAP decoder or a Soft Output Viterbi Algorithm (SOVA) decoder.

9. The transmission architecture combining Trellis Coded Modulation (TCM) and Low-Density Parity Check (LDPC) code according to claim 6, wherein said transmission channel can be a wired one or a wireless one.
